(19) United States
(12) Patent Application Publication
(10) Pub. No.: US 2012/0133597 A1
(43) Pub. Date: May 31, 2012

(54) ANTENNA STRUCTURE

(75) Inventor: Chih-Jung CHEN, TAIPEI CITY (TW)

(73) Assignee: INVENTEC CORPORATION, TAIPEI CITY (TW)

(21) Appl. No.: 13/028,226

(22) Filed: Feb. 16, 2011

(30) Foreign Application Priority Data
Nov. 30, 2010 (TW) 099141509

(51) Int. Cl. G06F 3/041; C30B 33/08; H01Q 1/22

(52) U.S. Cl. 345/173; 343/720; 216/23

(57) ABSTRACT

An antenna structure includes a coil unit formed by etching a conductive film in a non-display area of a display and a set of electrodes for transmitting signals connected to terminals of the coil unit. The antenna structure can be a near field communication antenna or a radio frequency identification antenna to transmit and receive signals with the coil unit formed in the non-display area of the display to save the occupation space in a portable communication device. Therefore, the antenna structure can effectively reduce the size of the portable communication device.

### RELATED APPLICATIONS

This application claims priority to Taiwan Application Serial Number 099141509, filed Nov. 30, 2010, which is herein incorporated by reference.

### BACKGROUND

1. Field of Invention

The present invention relates to an antenna structure, and more particularly, to an antenna structure formed on a display panel.

2. Description of Related Art

An antenna for receiving and transmitting signals is disposed in a portable communication device, e.g. an antenna for near field communication (NFC) or radio frequency identification (RFID). A current antenna structure is manufactured by winding a wire such as an enamel-covered wire into an induction coil, encapsulating the above induction coil with an insulating film and then disposing it within the portable communication device, or by directly making the wire such as the enamel-covered wire surround an interior of a case of the portable communication device to form the induction coil. A tap of the induction coil is electrically connected with a circuit board in the portable communication device and transfers signals received and transmitted by the antenna.

For a function of receiving and transmitting the signals, the above induction coil needs to have a larger induction range, thus occupying a space in the portable communication device and obstructing the reduction of the size of the portable communication device.

### SUMMARY

In view of the above, the present invention provides an antenna structure, which at least includes a coil unit formed in a non-display area of a display panel by etching a conductive film on the display panel and a set of electrodes located at terminals of the coil unit and electrically connected to the coil unit for transmitting signals.

In this case, the non-display area can surround a display area of the display panel. The conductive film can be an ITO film. The electrodes can be made of flexible circuit boards or probe-type electrodes.

When the antenna structure is manufactured, the coil unit can be formed on the same layer with a signal line or a scanning line of the display panel.

If the display panel is a touch-control display panel, the coil unit can be formed on the same layer with an X-axis touch-control line or a Y-axis touch-control line of the touch-control display panel. That is, the touch-control display panel can be a capacitive touch-control display panel.

The antenna structure of the present invention can be applied as a near field communication antenna, a radio frequency identification antenna, etc. the antenna structure can be immediately used with a conventional circuit element. Therefore, a research and development cost is saved. Moreover, with this configuration, forming the antenna structure in the non-display area of the display panel especially when the non-display area surrounds the display area of the display panel can save the occupation space in the portable communication device and can effectively reduce the size of the portable communication device.

Due to the fact that the coil unit can be formed on the same layer with the signal line or the scanning line of the display panel when the antenna structure is manufactured, a conventional ITO film for forming the signal line or the scanning line is used as the conductive film for forming the coil unit. This not only simplifies a manufacturing process, but also effectively thins the display panel.

If the antenna structure of the present invention is applied to the touch-control display panel, which is the same as the above antenna structure formed on a general display panel, the coil unit can be formed on the same layer with the X-axis touch-control line or the Y-axis touch-control line of the touch-control display panel. This not only simplifies the manufacturing process, but also effectively thins the touch-control display panel due to the fact that the coil unit can be formed on the same layer with the X-axis touch-control line or the Y-axis touch-control line.

The electrodes can be made of flexible circuit boards or can be probe-type electrodes. When the electrodes are made of the flexible circuit boards, positions of the display panel and a circuit board of the portable communication device, etc. can be flexibly designed and arranged, and the antenna structure is electrically connected with the circuit boards through the electrodes made of the flexible circuit boards. When the electrodes are the probe-type electrodes, wireless signals received by the antenna structure can be transmitted by the low-impedance probe-type electrodes with low leakage.

Moreover, the antenna structure of the present invention can further include a shielding layer covering the coil unit. The shielding layer inhibits a noise and improves the quality of transmitting the wireless signals.

It is to be understood that both the foregoing general description and the following detailed description are by examples, and are intended to provide further explanation of the invention as claimed.

### BRIEF DESCRIPTION OF THE DRAWINGS

In order to make the foregoing as well as other aspects, features, advantages, and embodiments of the present invention more apparent, the accompanying drawings are described as follows:

FIG. 1 is a schematic view illustrating that an antenna structure and X-axes are formed on a display panel;

FIG. 2 is a schematic view illustrating that a contact hole is formed on the display panel of FIG. 1; and

FIG. 3 is a schematic view illustrating that a conduction line and Y-axes are formed on the display panel of FIG. 2.

### DETAILED DESCRIPTION

The antenna structure of the present invention includes a coil unit 110 and electrodes 120. The coil unit 110 is formed in a non-display area of a display panel 900 by etching a conductive film on the display panel 900. The non-display area shown in the figures surrounds a display area 950 of the display panel 900, but the present invention is not limited to this. For example, the non-display area may also be located at any position, such as above the display area 950, below the display area 950, on the left of the display area 950, or on the right of the display area 950. The above conductive film can be a conductive film made of the same material as that of a signal line or a scanning line of the display panel 900, e.g. an ITO film. The electrodes 120 are located at terminals of the coil unit 110 and electronically connected to the coil unit 110 and a circuit board of a portable communication device equipped with the antenna structure (e.g. a mobile phone or a personal digital assistant) to transmit signals. The electrodes 120 can be made of flexible circuit boards or can be probe-type electrodes.

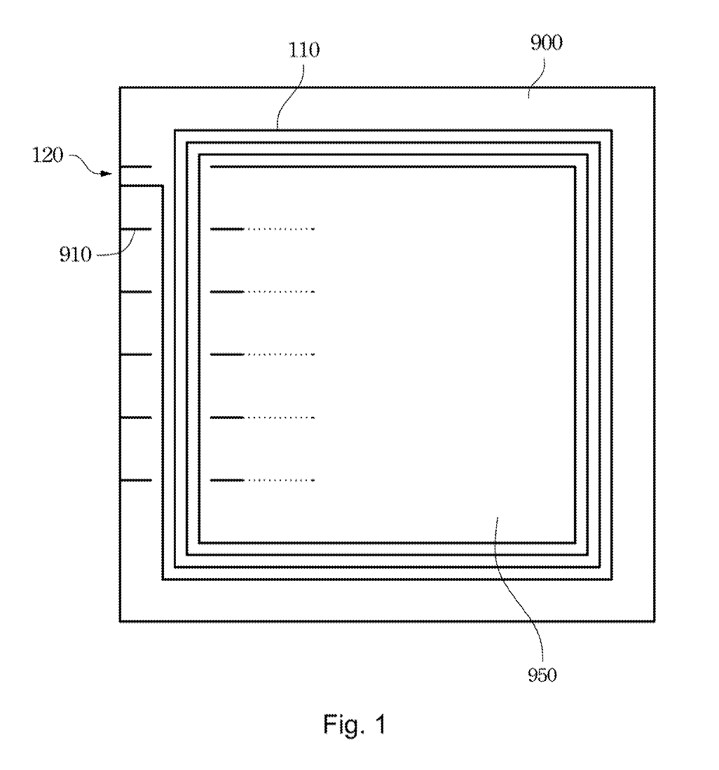

A method of manufacturing the antenna structure of the present invention includes the following steps. Firstly, as shown in FIG. 1, the coil unit 110 is formed in an area of the display panel 900 other than the display area 950 (i.e. the non-display area) and the electrodes 120 are formed at the terminals of the coil unit 110. While the coil unit 110 is formed, a plurality of X-axes (axes of a first layer) 910 can be formed in the display area 950 of the display panel 900 by using the conductive film which is at the same layer with the coil unit 110. After the above manufacturing process is finished, the whole surface of the display panel 900 is covered with at least one insulating layer (not shown). In FIG. 1, the coil unit 110 is formed into a rectangular scroll shape by winding a single conducting wire along an external edge of the display panel 900. One terminal of the coil unit 110 is located at an edge of the display panel 900 to be a terminal of the electrodes 120, and the other terminal of the coil unit 110 is located within the scroll shape wound by way of the coil unit 110. Likewise, the X-axes 910 are continuously conductive in the scroll shape wound by way of the coil unit 110, but the X-axes 910 in the scroll shape and the X-axes 910 at the edge of the display panel 900 for connecting an external circuit are disconnected due to the intervention of the coil unit 110.

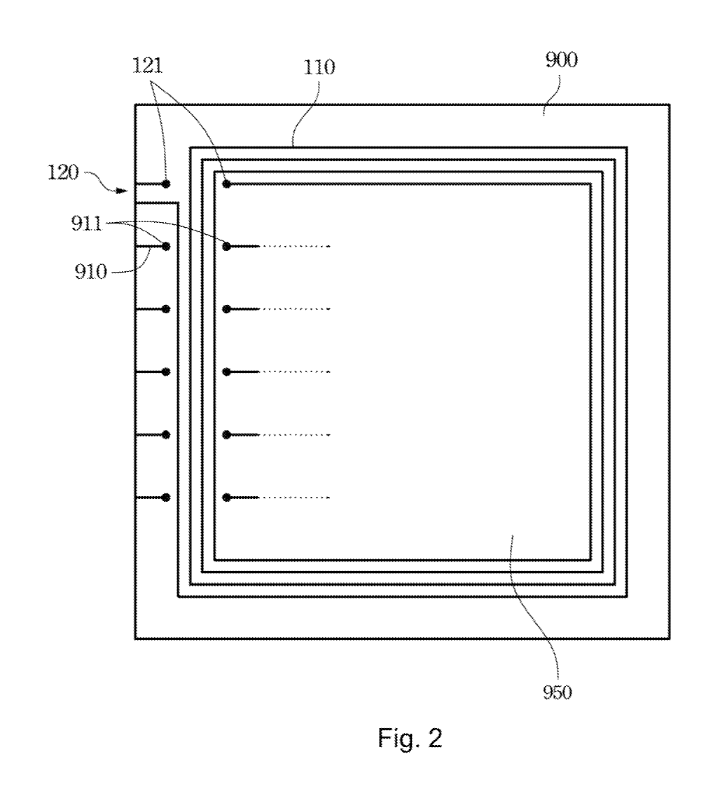

In view of the above, as shown in FIG. 2, through the insulating layer, a contact hole 121 is respectively formed at the other terminal of the coil unit 110 in the scroll shape and the other corresponding terminal of the electrodes 120. Likewise, through the insulating layer, a contact hole 911 is respectively formed at an edge terminal of the X-axes 910 in the scroll shape and a corresponding edge terminal of the X-axes 910 at the edge of the display panel 900.

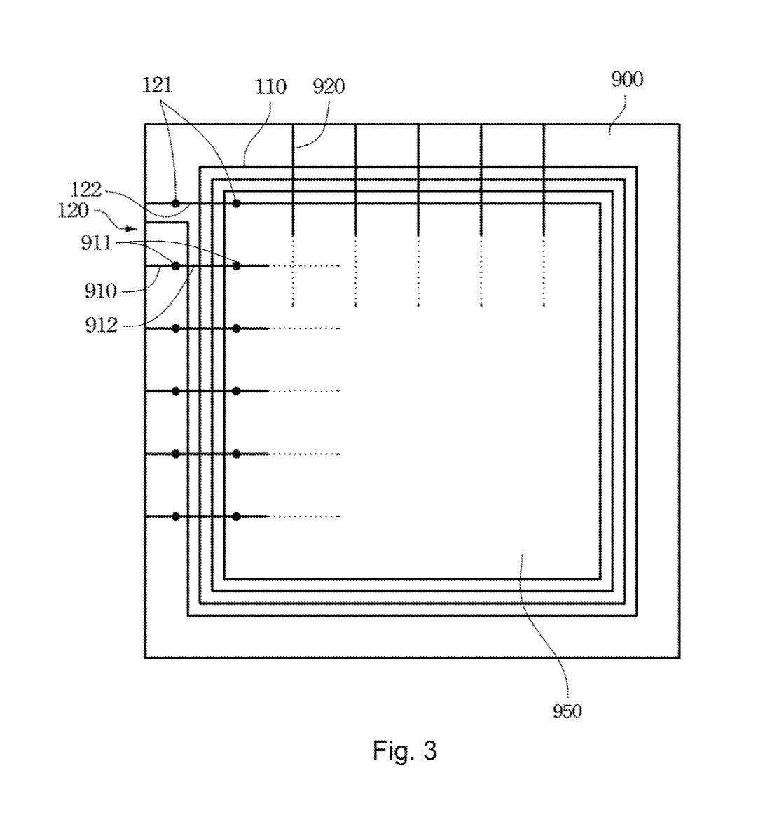

Then, as shown in FIG. 3, a conduction line 122 is formed between the two contact holes 121 to connect the terminal of the coil unit 110 in the scroll shape to the other terminal of the electrodes 120, so that the set of electrodes 120 can perform a function of receiving the signals of the coil unit 110. Likewise, a conduction line 912 is formed respectively between two corresponding contact holes 911 to connect the external circuit with the X-axes 910 in the scroll-shaped coil unit 110. In order to simplify the manufacturing process, the conduction lines 122 and 912 can be formed by a conductive film at the same layer, but the present invention is not limited to this. Moreover, while the conduction lines 122 and 912 are formed, a plurality of Y-axes (axes of a second layer) 920 can be formed in the display area 950 of the display panel 900 by using the conductive film which is at the same layer with any one of the conduction lines 122 and 912.

In the above manufacturing method, the X-axes 910 and the Y-axes 920 can be signal lines and scanning lines of the display panel 900. The above manufacturing steps are mainly intended to describe the method of manufacturing the antenna structure of the present invention. If elements in the display panel 900 such as a signal line, a scanning line and a TFT want to be manufactured while the antenna structure of the present invention is manufactured, steps of manufacturing the elements of the display panel 900 can be appropriately added to the above manufacturing method.

Moreover, when the display panel 900 is a touch-control display panel, the above X-axes 910 and Y-axes 920 can be touch-control lines. The X-axes 910 and the Y-axes 920 are in a cross arrangement as at least one insulating layer sandwiched between the X-axes 910 and the Y-axes 920, and thus the X-axes 910 and the Y-axes 920 form a capacitor at an intersection point. When a finger presses the touch-control display panel to operate it, the capacitor formed by the X-axes 910 and the Y-axes 920 at the intersection point changes a capacitance due to the operation of pressing, and thus a pressed position can be represented by a change of the capacitance between the X-axes 910 and the Y-axes 920. That is, the display panel 900 is a capacitive touch-control display panel.

Moreover, in consideration of the quality of the antenna structure for transmitting wireless signals, a distinct layer of the coil unit 110 can be covered with a shielding layer (not shown). A material of the shielding layer can be a material which can inhibit electromagnetic signals. The step of forming the shielding layer can also be appropriately added to the steps of manufacturing the display panel 900.

The above coil unit 110, the above electrodes 120, the above X-axes 910, the above Y-axes 920 and so on are not limited to the forms as shown in the figures, and the forms can be designed appropriately according to actual conditions, such as a shape of the coil unit 110, a position of the electrodes 120, numbers of the X-axes 910 and the Y-axes 920 and an interval between the X-axes 910 and the Y-axes 920. Moreover, related arts such as photolithography, exposure, imaging and etching applied for forming the above coil unit 110, the above electrodes 120, the above X-axes 910 and the above Y-axes 920 and related arts for manufacturing the display panel 900, the touch-control display panel and so on can use various conventional methods, which will not be described.

The antenna structure of the present invention can be a near field communication antenna or a radio frequency identification antenna to receive and transmit signals with the coil unit formed in the non-display area of the display panel to save the occupation space in the portable communication device. Therefore, the antenna structure can effectively reduce the size of the portable communication device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An antenna structure, comprising:
a coil unit formed in a non-display area of a display panel by etching a conductive film on the display panel; and
a set of electrodes located at terminals of the coil unit and electrically connected to the coil unit for transmitting signals.

2. The antenna structure of claim 1, wherein the non-display area surrounds a display area of the display panel.

3. The antenna structure of claim 1, wherein the conductive film is an ITO film.

4. The antenna structure of claim 1, wherein the electrodes are made of flexible circuit boards.

5. The antenna structure of claim 1, wherein the electrodes are probe-type electrodes.

6. The antenna structure of claim 1, wherein the antenna structure is a near field communication antenna.

7. The antenna structure of claim 1, wherein the antenna structure is a radio frequency identification antenna.

8. The antenna structure of claim 1, wherein the antenna structure further comprises a shielding layer covering the coil unit.

9. The antenna structure of claim 1, wherein the coil unit and a signal line of the display panel are formed on the same layer.

10. The antenna structure of claim 1, wherein the coil unit and a scanning line of the display panel are formed on the same layer.

11. A touch-control display panel, comprises the antenna structure of claim 1.

12. The touch-control display panel of claim 11, wherein the touch-control display panel is a capacitive touch-control display panel.

13. The touch-control display panel of claim 12, wherein the coil unit and an X-axis touch-control line of the capacitive touch-control display panel are formed on the same layer.

14. The touch-control display panel of claim 12, wherein the coil unit and a Y-axis touch-control line of the capacitive touch-control display panel are formed on the same layer.

15. A method of manufacturing a touch-control display panel, at least comprising:
etching a conductive film of a touch-control display panel to form a coil unit in a non-display area of the touch-control display panel.

16. The method of manufacturing the touch-control display panel of claim 15, further comprising forming a shielding layer to cover the coil unit.

17. The method of manufacturing the touch-control display panel of claim 15, further comprising etching the conductive film to form a first layer touch-control line while etching the conductive film of touch-control display panel to form the coil unit in the non-display area of the touch-control display panel.

18. The method of manufacturing the touch-control display panel of claim 17, further comprising covering the coil unit and the first layer touch-control line with at least an insulating layer.

19. The method of manufacturing the touch-control display panel of claim 18, further comprising forming a contact hole through the insulating layer at the position of the coil unit and the first layer touch-control line.

20. The method of manufacturing the touch-control display panel of claim 18, further comprising forming a second layer touch-control line on the insulating layer.
